(19) United States
(12) Patent Application Publication
(10) Pub. No.: US 2024/0155821 A1
(43) Pub. Date: May 9, 2024

(54) COMPONENT MOUNTING APPARATUS, COMPONENT MOUNTING METHOD, AND COMPONENT POSITIONAL RELATIONSHIP INFORMATION ACQUIRING METHOD

(71) Applicant: Murata Manufacturing Co., Ltd., Kyoto-fu (JP)

(72) Inventors: Yoshiaki SATAKE, Nagaokakyo-shi (JP); Masayuki AOIKE, Nagaokakyo-shi (JP); Tatsuya FUNAKI, Nagaokakyo-shi (JP)

(73) Assignee: Murata Manufacturing Co., Ltd., Kyoto-fu (JP)

(21) Appl. No.: 18/503,663

(22) Filed: Nov. 7, 2023

(30) Foreign Application Priority Data
Nov. 8, 2022 (JP) 2022-178817

(51) Int. Cl. H05K 13/00; H05K 13/04; H05K 13/08

(52) U.S. Cl. CPC H05K 13/0015; H05K 13/0409; H05K 13/0812; H05K 13/0818

(57) ABSTRACT

A mounting nozzle is capable of holding an electronic component having multiple patterns provided on its pattern surface based on pattern design information. A camera is capable of capturing an image of the pattern surface of the electronic component. A movement mechanism is capable of moving the mounting nozzle between a location where capturing of the image by the camera is performed and a component mounting location. A control unit is capable of controlling the mounting nozzle and the movement mechanism. The control unit stores positional relationship information indicating positional relationship based on the pattern design information between a position of a registration pattern representative point identified by at least one registration pattern selected from the multiple patterns provided on the pattern surface and a position of a positioning reference point on which positioning of the electronic component at the component mounting location for mounting is based.

### CROSS-REFERENCE TO RELATED APPLICATION

This application claims benefit of priority to Japanese Patent Application No. 2022-178817, filed Nov. 8, 2022, the entire content of which is incorporated herein by reference.

### BACKGROUND

### Technical Field

The present disclosure relates to a component mounting apparatus, a component mounting method, and a component positioning method.

### Background Art

In mounting of an electronic component on a substrate, an image recognition method is known in which an image of a pattern to be detected, such as the electronic component or a substrate mark, is captured to recognize the position of the pattern to be detected in order to accurately mount the electronic component at a certain position as described in Japanese Unexamined Patent Application Publication No. 2002-216130. In the image recognition method, an image of the pattern to be detected is captured and matching between a predetermined reference pattern and the pattern to be detected is performed to detect the center position of the pattern to be detected. The electronic component is mounted at a certain mounting position based on the center position of the pattern to be detected.

In positioning of an electronic component at a target position, a reference point (a positioning reference point) of the electronic component, which is to be positioned at the target position, is set based on multiple patterns provided for the electronic component. The shapes and the positions of the patterns are defined in pattern design information. The position of the positioning reference point is also defined based on the pattern design information.

The center position of the pattern to be detected, which is obtained through image recognition of the electronic component, does not necessarily coincide with the position of the positioning reference point. Even if the center position of the pattern to be detected is positioned at the target position, the positioning reference point does not coincide with the target position. In order to match the positioning reference point with the target position, the center position of the pattern to be detected is positioned and mounted at the target position on trial. In this state, the mounting position of the electronic component is measured. The amount of shift between the measured mounting position and the target mounting position substantially corresponds to the amount of shift between the center position of the pattern to be detected and the position of the positioning reference point. Accordingly, the amount of shift between the center position of the pattern to be detected and the position of the positioning reference point is capable of being obtained from the amount of shift between the measured mounting position and the target mounting position. In practical mounting of the electronic component, the electronic component is positioned so as to compensate the amount of shift between the center position of the pattern to be detected and the position of the positioning reference point.

### SUMMARY

As described above, it is necessary to perform the complicated process to mount the electronic component on trial and measure the position of the electronic component in order to obtain the amount of shift between the center position of the pattern to be detected and the position of the positioning reference point. Accordingly, the present disclosure provides a component mounting apparatus, a component mounting method, and a component positioning method, which are capable of simplifying the process to position the electronic component at the target position and improving the positioning accuracy.

According to an aspect of the present disclosure, a component mounting apparatus includes a mounting nozzle capable of holding an electronic component having multiple patterns provided on its pattern surface based on pattern design information; a camera capable of capturing an image of the pattern surface of the electronic component; a movement mechanism capable of moving the mounting nozzle between a location where capturing of the image by the camera is performed and a component mounting location; and a control unit capable of controlling the mounting nozzle and the movement mechanism. The control unit has a function to store positional relationship information indicating positional relationship based on the pattern design information between a position of a registration pattern representative point identified by at least one registration pattern selected from the multiple patterns provided on the pattern surface and a position of a positioning reference point on which positioning of the electronic component at the component mounting location for mounting is based. The control unit also has a function to acquire an image of the pattern surface of the electronic component, which is captured by the camera, a function to analyze the image to obtain the position of the registration pattern representative point, and a function to position the positioning reference point obtained from the position of the registration pattern representative point resulting from the analysis of the image and the positional relationship information at a target position at the component mounting location to mount the electronic component.

According to another aspect of the present disclosure, a component mounting method includes storing in advance positional relationship information indicating positional relationship based on pattern design information between a position of a registration pattern representative point identified by at least one registration pattern selected from multiple patterns provided on a pattern surface of an electronic component based on the pattern design information and a position of a positioning reference point on which positioning of the electronic component at a component mounting location for mounting is based; and holding the electronic component with a mounting nozzle. The component mounting method also includes acquiring an image of the pattern surface of the electronic component held with the mounting nozzle; analyzing the image to obtain the position of the registration pattern representative point; and positioning the positioning reference point obtained from the position of the registration pattern representative point resulting from the analysis of the image and the positional relationship information at a target position at the component mounting location to mount the electronic component.

According to another aspect of the present disclosure, a positional relationship information acquiring method includes acquiring an image of a pattern surface having multiple patterns formed thereon of an electronic component; displaying the image to cause a user to select a registration pattern from the multiple patterns and to cause the user to specify a pattern matching area including some patterns in the multiple patterns; storing information for identifying the registration pattern selected by the user and information for identifying the pattern matching area specified by the user; and calculating a position of a registration pattern representative point based on pattern design information that defines shapes and positions of the multiple patterns on the pattern surface and the information for identifying the registration pattern. The positional relationship information acquiring method also includes calculating positional relationship between a positioning reference point on which positioning to a target position where the electronic component is to be mounted is based and the position of the registration pattern representative point based on the pattern design information; and acquiring and storing positional relationship information between the positioning reference point and the registration pattern representative point.

Since the positional relationship information between the position of the registration pattern representative point and the position of the positioning reference point on which the positioning is based is obtained based on the pattern design information, the positioning reference point is capable of being positioned to the target position to mount the electronic component without mounting the electronic component on trial and measuring a positional shift. As a result, it is possible to simplify the process to position the electronic component to the target position and to improve the positioning accuracy.

### BRIEF DESCRIPTION OF THE DRAWINGS

FIG. 1 is a schematic diagram of a component mounting apparatus according to a first embodiment;

FIG. 2 illustrates the relationship between multiple coordinate systems;

FIG. 3 is a flowchart illustrating a process to obtain positional relationship information;

FIG. 4A, FIG. 4B, and FIG. 4C are diagrams illustrating how multiple patterns are disposed on a pattern surface of an electronic component in design;

FIG. 5 is a flowchart indicating a process to mount a component by the component mounting apparatus according to the first embodiment;

FIG. 6A and FIG. 6B are diagrams illustrating the pattern surface of the electronic component attracted by a mounting nozzle;

FIG. 7 is a diagram illustrating the pattern surface of the electronic component to be targeted in a component mounting apparatus according to a second embodiment;

FIG. 8 is a diagram illustrating the pattern surface of the electronic component to be targeted in a component mounting apparatus according to a third embodiment;

FIG. 9 is a diagram illustrating the pattern surface of the electronic component to be targeted in a component mounting apparatus according to a modification of the third embodiment; and

FIG. 10 is a schematic front view of part of a component mounting apparatus according to a fourth embodiment.

### DETAILED DESCRIPTION

### First Embodiment

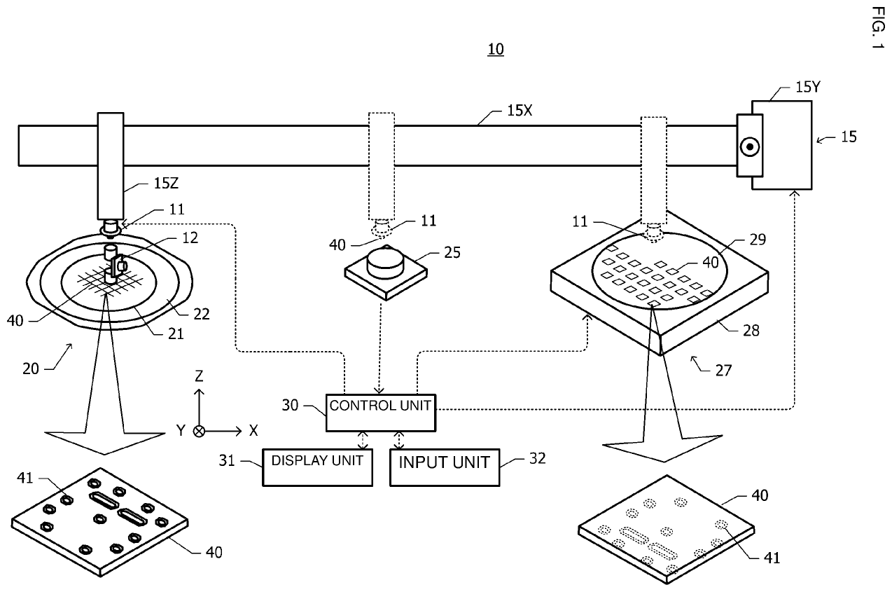

A component mounting apparatus according to a first embodiment will herein be described with reference to FIG. 1 to FIG. 6B.

FIG. 1 is a schematic diagram of a component mounting apparatus 10 according to the first embodiment. The component mounting apparatus 10 picks up an electronic component 40 from a component supply location 20, positions the electronic component 40 at a target position on a substrate 29 disposed at a component mounting location 27, and mounts the electronic component 40 that is positioned.

An XYZ orthogonal coordinate system is defined in which the upper vertical direction is set as the positive direction of the Z axis. A movement mechanism 15 includes an X-direction movement mechanism 15X, a Y-direction movement mechanism 15Y, and a Z-direction movement mechanism 15Z. The Y-direction movement mechanism 15Y includes a guide rail parallel to the Y direction and moves the X-direction movement mechanism 15X in the Y direction under the control of a control unit 30. The X-direction movement mechanism 15X includes a guide rail parallel to the X direction and moves the Z-direction movement mechanism 15Z in the X direction under the control of the control unit 30. The Z-direction movement mechanism 15Z moves (moves up and down) a mounting nozzle 11 in the Z direction under the control of the control unit 30. In other words, the movement mechanism 15 moves the mounting nozzle 11 in the X direction, the Y circuit, and the Z direction to move the electronic component 40 held at the mounting nozzle 11 between the component supply location 20, a location where capturing of an image by a camera 25 is performed, and the component mounting location 27.

An operation of the component mounting apparatus 10 at the component supply location 20 will now be described.

Multiple electronic components 40 resulting from cutting a wafer 21 attached to a dicing tape 22 into individual pieces with a dicing machine are supplied to the component supply location 20. Multiple patterns 41, for example, external connection terminals such as pads are provided on a pattern surface, which is one surface of each of the electronic components 40. A surface opposite to the pattern surface (hereinafter referred to as a rear surface) is attached to the dicing tape 22 and the pattern surfaces of the electronic components 40 are exposed.

The electronic components 40 are thrust upward from the lower side with a needle-shaped long jig, which is called a needle, and the pattern surface of each of the electronic components 40 is suctioned by a reversing nozzle 12 to cause the electronic component 40 to be attracted to the reversing nozzle 12. The reversing nozzle 12 is reversed to direct the rear surface of the electronic component 40 upward. The mounting nozzle 11 suctions the rear surface of the electronic component 40 in this state and the suction by the reversing nozzle 12 is stopped to cause the electronic component 40 to be attracted to the mounting nozzle 11. In the state in which the electronic component 40 is attracted to the mounting nozzle 11, the pattern surface of the electronic component 40 is directed downward (toward the negative direction of the Z axis). The above operations are performed under the control of the control unit 30.

The electronic components 40 may be supplied to the component supply location 20 using an electronic component tray, a part feeder (an automatic component supply device), or the like. In the supply of the electronic components 40 with the electronic component tray, the electronic components 40 housed in the electronic component tray are suctioned by the reversing nozzle 12 without using the needle. In the supply of the electronic components 40 with the part feeder, the electronic components 40 the pattern surfaces of which are directed downward are suctioned by the mounting nozzle 11 not via the reversing nozzle 12.

An operation of the component mounting apparatus 10 at the position of the camera 25 will now be described.

The camera 25 is fixed so as to be directed upward (toward the positive direction of the Z axis). The electronic components 40 are disposed within the angle of view (visual field) of the camera 25 in the state in which the mounting nozzle 11 suctions the electronic components 40. The camera 25 captures images of the pattern surfaces of the electronic components 40. The captured images are supplied to the control unit 30.

An operation of the component mounting apparatus 10 at the component mounting location 27 will now be described. A stage 28 is disposed at the component mounting location 27 and the substrate 29 on which the electronic components 40 are to be mounted is held on the stage 28. Multiple target positions at which the electronic components 40 are to be mounted are defined on a component mounting surface of the substrate 29. For example, positioning marks are formed on the component mounting surface of the substrate 29 and the target positions are defined by the relative positions with respect to the positioning marks.

For example, the electronic components 40 are bonded to the substrate 29 with a bonding layer provided on the component mounting surface of the substrate 29 in a state in which the pattern surfaces having the multiple patterns 41 are opposed to the substrate 29. Next, an example of a process after the multiple electronic components 40 are mounted on the substrate 29 will be described.

For example, after the multiple electronic components 40 are bonded to the component mounting surface of the substrate 29, a semiconductor substrate having a circuit pattern formed thereon may be placed on the multiple electronic components 40 to transfer the multiple electronic components 40 from the substrate 29 to the semiconductor substrate. Since the multiple electronic components 40 are positioned and bonded to the substrate 29, positioning the substrate 29 and the semiconductor substrate causes the multiple electronic components 40 to be positioned and fixed to the semiconductor substrate.

Alternatively, the positioning mark or the pattern may be formed at each of the multiple target positions on the component mounting surface of the substrate 29. For example, the external connection terminals with solder, which are provided on the pattern surfaces of the electronic components 40, may be placed on lands provided on the component mounting surface of the substrate 29 and a reflow process of the solder may be performed to stick the electronic components 40 on the substrate 29.

The control unit 30 controls the mounting nozzle 11, the reversing nozzle 12, the movement mechanism 15, and the stage 28. A display unit 31 displays a variety of information as images or characters under the control of the control unit 30. A variety of information necessary for a component mounting process is input with an input unit 32. For example, a liquid crystal display, an organic electroluminescence (EL) display, or the like is used as the display unit 31. For example, a mouse, a touch panel, a touch pad, another pointing device, a keyboard, or the like is used as the input unit 32.

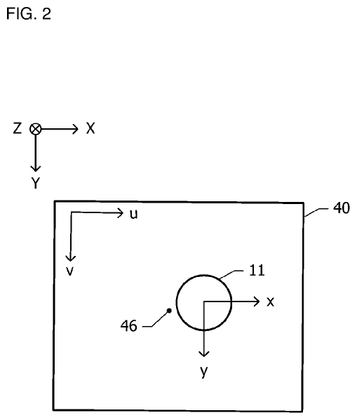

The meaning of the “position” used in this specification will now be described with reference to FIG. 2.

FIG. 2 illustrates the relationship between multiple coordinate systems. The XYZ orthogonal coordinate system is defined for the component mounting apparatus 10, as illustrated in FIG. 1. An xy orthogonal coordinate system based on the position of the mounting nozzle 11 is defined on the pattern surface of the electronic component 40 attracted to the mounting nozzle 11. The xy orthogonal coordinate system is moved with the movement of the mounting nozzle 11 with respect to the XYZ orthogonal coordinate system.

In addition to the xy orthogonal coordinate system, a uv orthogonal coordinate system is defined on the pattern surface of the electronic component 40. The uv orthogonal coordinate system is used in pattern design information defining the shapes and the positions of the multiple patterns on the pattern surface. In other words, the uv orthogonal coordinate system is fixed with respect to the electronic components 40. When the position where the electronic component 40 is attracted by the mounting nozzle 11 is varied, the relative positional relationship between the xy coordinate and the uv coordinate is varied.

A positioning reference point 46 for positioning at the target position at the component mounting location 27 (FIG. 1) is defined on the pattern surface of the electronic component 40. For example, the geometrical center of the multiple patterns defined on the pattern surface may be adopted as the positioning reference point 46. The uv coordinate of the positioning reference point 46 is determined in design of the patterns. In order to position the electronic component 40 at the target position at the component mounting location 27 (FIG. 1), it is necessary to obtain the xy coordinate of the positioning reference point 46.

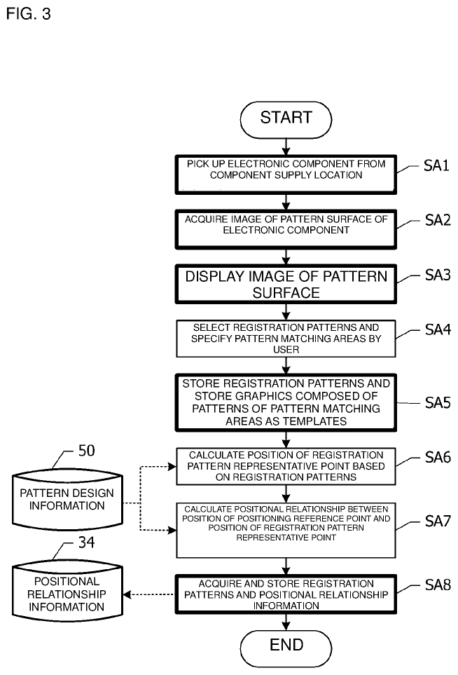

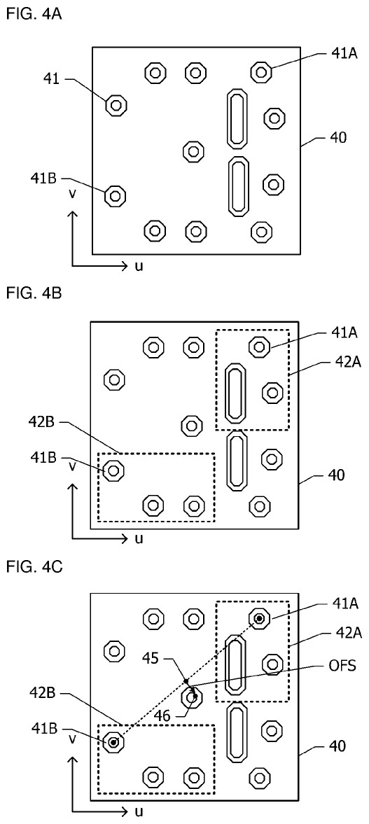

Positional relationship information stored in the control unit 30 in the component mounting apparatus 10 (FIG. 1) according to the first embodiment will now be described with reference to FIG. 3 to FIG. 4C. FIG. 3 is a flowchart illustrating a process to obtain the positional relationship information. Among steps indicated in FIG. 3, Steps SA1, SA2, SA3, SA5, and SA8 surrounded by bold lines are performed under the control of the control unit 30 (FIG. 1). Steps SA4, SA6, and SA7 surrounded by thin lines are performed by a user. FIG. 4A, FIG. 4B, and FIG. 4C are diagrams illustrating how the multiple patterns are disposed on the pattern surface of the electronic component 40 in design.

Referring to FIG. 3, in Step SA1, the mounting nozzle 11 attracts the electronic component 40 to pick up the electronic component 40 from the component supply location 20. The electronic component 40 attracted to the mounting nozzle 11 is moved into the angle of view of the camera 25 and an image of the pattern surface of the electronic component 40 is captured. In Step SA2, the control unit 30 acquires the image of the pattern surface from the camera 25. In Step SA3, the control unit 30 displays the acquired image in the display unit 31.

For example, the shapes and the positions of the multiple patterns 41 are defined on the pattern surface of the electronic component 40 in a manner illustrated in FIG. 4A. The multiple patterns illustrated in FIG. 4A are formed on the pattern surface of the electronic component 40. The multiple patterns 41 include, for example, patterns of a regular polygonal shape, a circular shape, and a long strip shape.

In Step SA4, the user selects two patterns from the multiple patterns 41 on the display unit 31. The patterns selected by the user are referred to as registration patterns. For example, two registration patterns of a first registration pattern 41A and a second registration pattern 41B are selected, as illustrated in FIG. 4A.

The registration patterns that sandwich the geometrical center of the pattern surface and that are apart from each other are preferably selected as the two registration patterns. In addition, the registration pattern of the shape, the position of the geometrical center of which is capable of being accurately determined through image analysis of the pattern, for example, the registration pattern of a circular shape or a regular polygonal shape is preferably selected as the registration pattern.

In Step SA4, the user specifies a first pattern matching area 42A including the first registration pattern 41A and other patterns 41 and a second pattern matching area 42B including the second registration pattern 41B and other patterns 41, as illustrated in FIG. 4B. Areas including characteristic disposition or shapes of the patterns are preferably specified as the first pattern matching area 42A and the second pattern matching area 42B. In Step SA5, the control unit 30 stores the registration patterns (for example, the positional information about the registration patterns) and stores a graphic composed of the patterns of each of the first pattern matching area 42A and the second pattern matching area 42B as a pattern matching template.

After the first registration pattern 41A and the second registration pattern 41B are determined, in Step SA6, the user calculates the position of a registration pattern representative point 45 (FIG. 4C) using pattern design information 50. Next, a method of calculating the position of the registration pattern representative point 45 will be described with reference to FIG. 4C.

As illustrated in FIG. 4C, the center position (the uv coordinate) of each of the first registration pattern 41A and the second registration pattern 41B is calculated from the pattern design information 50 (FIG. 3). The midpoint of a line segment both ends of which are the two center positions is adopted as the registration pattern representative point 45. The position (the uv coordinate) of the registration pattern representative point 45 is calculated from the center position of each of the first registration pattern 41A and the second registration pattern 41B. The position (the uv coordinate) of the positioning reference point 46, on which the positioning of the electronic component 40 at the target position at the component mounting location 27 is based, is determined in advance. As one example, the center of the pattern surface of the electronic component 40 is used as the positioning reference point 46.

In Step SA7, the user calculates the positional relationship between the position of the registration pattern representative point 45 and the position of the positioning reference point 46 based on the pattern design information 50. Information representing the positional relationship between the position of the registration pattern representative point 45 and the position of the positioning reference point 46 is referred as positional relationship information 34. As one example, the positional relationship information 34 is defined by offset amounts OFS in the u-axis direction and the v-axis direction from the position of the registration pattern representative point 45 to the position of the positioning reference point 46.

The user inputs the positional relationship information 34 into the input unit 32 (FIG. 1). In Step SA8, the control unit 30 acquires the positional relationship information 34 input into the input unit 32 and stores the acquired positional relationship information 34 in a memory.

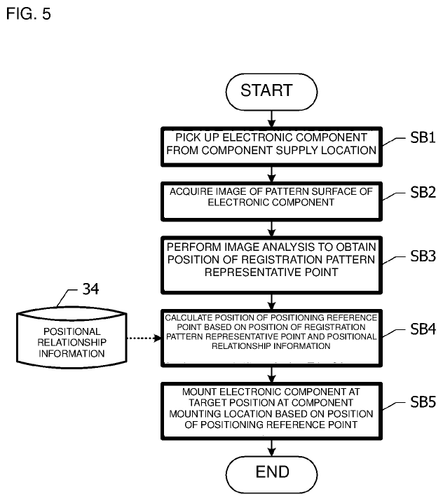

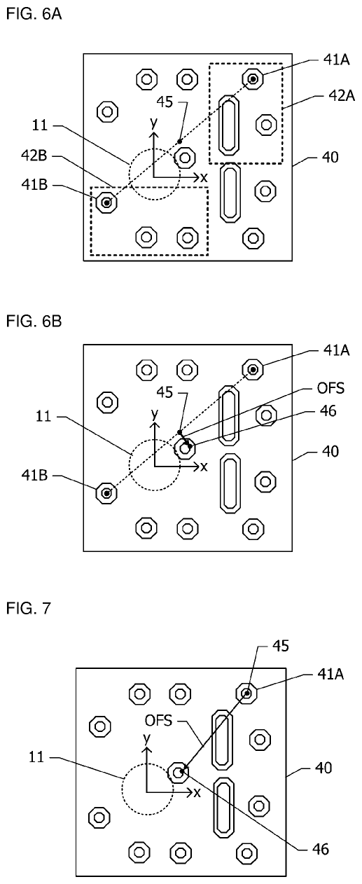

A process to mount a component by the component mounting apparatus 10 according to the first embodiment will be described with reference to FIG. 5 to FIG. 6B. FIG. 5 is a flowchart indicating the process to mount a component by the component mounting apparatus 10 according to the first embodiment. The respective steps in FIG. 5 are performed under the control of the control unit 30 (FIG. 1). FIG. 6A and FIG. 6B are diagrams illustrating the pattern surface of the electronic component 40 attracted by the mounting nozzle 11.

Referring to FIG. 5, in Step SB1, the mounting nozzle 11 (FIG. 1) picks up the electronic component 40 from the component supply location 20. In Step SB2, the control unit 30 moves the electronic component 40 picked up by the mounting nozzle 11 into the field of view of the camera 25 (FIG. 1) to acquire an image of the pattern surface of the electronic component 40. In Step SB3, the control unit 30 performs the image analysis to obtain the position of the registration pattern representative point 45.

An example of Step SB3 will now be described with reference to FIG. 6A. The electronic component 40 is attracted to the mounting nozzle 11. A pattern matching process is performed using the template of the first pattern matching area 42A to detect the first pattern matching area 42A. As a result, the position of the first registration pattern 41A is coarsely detected. After the first pattern matching area 42A is detected, the first registration pattern 41A in the first pattern matching area 42A is detected. After the first registration pattern 41A is detected, the image of the first registration pattern 41A is analyzed to obtain the position (the xy coordinate) of the center point of the first registration pattern 41A. The position (the xy coordinate) of the center point of the second registration pattern 41B is obtained in the same manner.

The midpoint of the line segment between the center point of the first registration pattern 41A and the center point of the second registration pattern 41B is adopted as the registration pattern representative point 45. The position (the xy coordinate) of the registration pattern representative point 45 is calculated from the position of the center point of the first registration pattern 41A and the position of the center point of the second registration pattern 41B.

Referring back to FIG. 5, in Step SB4, the position (the xy coordinate) of the positioning reference point 46 is calculated based on the position of the registration pattern representative point 45 and the positional relationship information 34.

An example of Step SB4 will now be described with reference to FIG. 6B. The positional relationship information 34 includes the offset amounts OFS from the position of the registration pattern representative point 45 to the position of the positioning reference point 46. The position of the positioning reference point 46 is capable of being calculated from the position of the registration pattern representative point 45 and the offset amounts OFS.

Referring back to FIG. 5, after the position of the positioning reference point 46 is obtained, in Step SB5, the control unit 30 positions the positioning reference point 46 at the target position at the component mounting location 27 (FIG. 1) to mount the electronic component 40 on the substrate 29.

Excellent advantages of the first embodiment will now be described.

In the method in related art, the electronic component 40 is mounted on the substrate 29 on trial in order to obtain the amount of shift between the center position of the pattern to be detected and the position of the positioning reference point on the pattern surface of the electronic component 40. Then, the positional relationship between the position of the electronic component 40, which is mounted on trial, and the actual target position is measured to obtain the positional relationship between the registration pattern representative point 45 and the positioning reference point 46.

In contrast, in the first embodiment, the positional relationship information 34 indicating the positional relationship between the position of the registration pattern representative point 45 (FIG. 4C) and the position of the positioning reference point 46 (FIG. 4C) is calculated using the pattern design information 50 (FIG. 3) (in Step SA7). Accordingly, the positional relationship information 34 is capable of being acquired without performing the complicated process to mount the electronic component 40 on the substrate 29 on trial.

In the method of mounting the electronic component 40 on the substrate 29 on trial, mechanical variation in the mounting position and variation involved in the measurement of the mounting position are included in the positional relationship information. In particular, when no pattern is formed on the rear surface of the electronic component 40, the position of the electronic component 40 is measured through analysis of the image of the outline of the electronic component 40. The outline of the electronic component 40 also includes variation in position in the cutting with the dicing machine. Accordingly, various errors are included in the positional relationship information. The inclusion of the errors in the positional relationship information 34 reduces mounting position accuracy of the electronic components 40.

In contrast, in the first embodiment, since the positional relationship information 34 is obtained using the pattern design information 50 (FIG. 3), the accuracy of the positional relationship information 34 is capable of being improved. As a result, it is possible to improve the mounting position accuracy of the electronic components 40.

A modification of the first embodiment will now be described.

In the first embodiment, when the electronic component 40 is attracted by the mounting nozzle 11, positioning in a rotation direction around an axis parallel to the Z direction (FIG. 1) is not referred to. In the present modification, a case is described in which the positioning in the rotation direction is not completed when the electronic component 40 is picked up by the mounting nozzle 11. In this case, the mounting nozzle 11 may be provided with a mechanism to perform the positioning in the rotation direction of the electronic component 40. The control unit 30 obtains the position in the rotation direction from the center position of the first registration pattern 41A and the center position of the second registration pattern 41B illustrated in FIG. 6A. Then, the electronic component 40 may be rotated so as to match the obtained position in the rotation direction with the target position.

The control unit 30 stores frequently appearing patterns 41, among the multiple patterns 41 on the pattern surface of the electronic component 40. For example, a pattern of a circular shape, a regular polygonal shape, or the like may be adopted as the frequently appearing pattern. In the case of the pattern of a circular shape or a regular polygonal shape, the center position has a small error when the center position is obtained through the image analysis. In the display of the image of the pattern surface of the electronic component 40 in the display unit 31 in Step SA3 (FIG. 3), the control unit 30 may display the frequently appearing patterns so as to be discriminated from the other patterns. For example, the control unit 30 may highlight the frequently appearing patterns, compared with the other patterns, for display.

The user selects the registration patterns from the frequently appearing patterns in Step SA4 (FIG. 3). Since the user is capable of discriminating the frequently appearing patterns from the other patterns, the user is capable of easily performing the registration of the registration patterns.

### Second Embodiment

A component mounting apparatus according to a second embodiment will herein be described with reference to FIG. 7. A description of the configuration common to that of the component mounting apparatus according to the first embodiment described above with reference to FIG. 1 to FIG. 6B is omitted herein.

FIG. 7 is a diagram illustrating the pattern surface of the electronic component 40 to be targeted in the component mounting apparatus according to the second embodiment. In the first embodiment (FIG. 6A), the two registration patterns: the first registration pattern 41A and the second registration pattern 41B are registered. In contrast, in the second embodiment, the only one first registration pattern 41A is registered. In order to detect the first registration pattern 41A, for example, a characteristic pattern matching area including the first registration pattern 41A is defined. The position of this pattern matching area may be detected and, then, the first registration pattern 41A in the pattern matching area may be detected. The registration pattern representative point 45 is determined based on the position of the one first registration pattern 41A. For example, the center position of the first registration pattern 41A is adopted as the registration pattern representative point 45. As in the first embodiment, the offset amounts OFS from the registration pattern representative point 45 to the positioning reference point 46 are defined as the positional relationship information 34 (FIG. 3 and FIG. 5).

Excellent advantages of the second embodiment will now be described.

The positional relationship information 34 is capable of being acquired without performing the complicated process to mount the electronic component 40 on the substrate 29 (FIG. 1) on trial also in the second embodiment, as in the first embodiment. In addition, as in the first embodiment, since the accuracy of the positional relationship information 34 is capable of being improved, it is possible to improve the mounting position accuracy of the electronic components 40.

Since the position of the registration pattern representative point 45 is determined from the result of the image analysis of the one first registration pattern 41A in the second embodiment, the positioning accuracy is slightly degraded, compared with the first embodiment in which the position of the registration pattern representative point 45 is determined from the result of the image analysis of the two patterns: the first registration pattern 41A and the second registration pattern 41B. However, since there is no need to perform the image analysis of the two registration patterns, an excellent advantage of short processing time is achieved. Whether one registration pattern is used or two registration patterns are used may be determined based on the result of comparison between the required positioning accuracy and the request for the short processing time. Three or more registration patterns may be used in order to improve the positioning accuracy.

### Third Embodiment

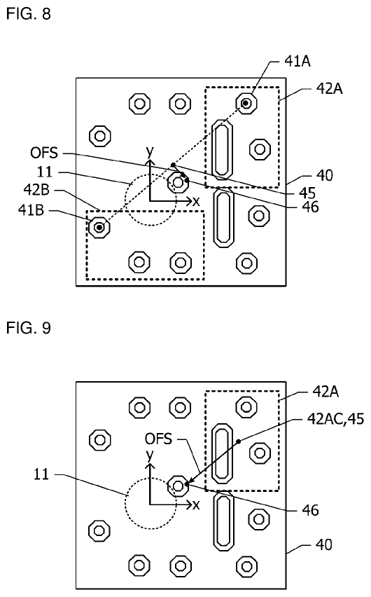

A component mounting apparatus according to a third embodiment will herein be described with reference to FIG. 8. A description of the configuration common to that of the component mounting apparatus according to the first embodiment described above with reference to FIG. 1 to FIG. 6B is omitted herein.

FIG. 8 is a diagram illustrating the pattern surface of the electronic component 40 to be targeted in the component mounting apparatus according to the third embodiment. In the first embodiment (FIG. 4C and FIG. 6A), the first registration pattern 41A in the first pattern matching area 42A is detected, the second registration pattern 41B in the second pattern matching area 42B is detected, and the position of the registration pattern representative point 45 is obtained based on the detected positions. In contrast, in the third embodiment, the first pattern matching area 42A and the second pattern matching area 42B are detected without detecting the first registration pattern 41A and the second registration pattern 41B to calculate the position of the registration pattern representative point 45.

For example, the positional relationship between the first pattern matching area 42A and the first registration pattern 41A and the positional relationship between the second pattern matching area 42B and the second registration pattern 41B are registered in advance. The positions of the first registration pattern 41A and the second registration pattern 41B are capable of being calculated from the result of detection of the first pattern matching area 42A and the second pattern matching area 42B and the positional relationship that is registered in advance.

In the third embodiment, in Step SB3 (FIG. 5), the position of the first pattern matching area 42A is obtained from the result of the pattern matching using the template of the first pattern matching area 42A. The position of the second pattern matching area 42B is obtained in the same manner.

After obtaining the positions of the first pattern matching area 42A and the second pattern matching area 42B, the positions of the first registration pattern 41A and the second registration pattern 41B are calculated using the positional relationship that is registered in advance. The position (the xy coordinate) of the registration pattern representative point 45 is calculated from the positions of the first registration pattern 41A and the second registration pattern 41B. Then, the position (the xy coordinate) of the positioning reference point 46 is calculated from the position of the registration pattern representative point 45 and the positional relationship information 34, as in the first embodiment (FIG. 5).

Excellent advantages of the third embodiment will now be described.

The positional relationship information 34 is capable of being acquired without performing the complicated process to mount the electronic component 40 on the substrate 29 (FIG. 1) on trial also in the third embodiment, as in the first embodiment. In addition, as in the first embodiment, since the accuracy of the positional relationship information 34 is capable of being improved, it is possible to improve the mounting position accuracy of the electronic components 40.

In the first embodiment (FIG. 6A), after the first pattern matching area 42A is detected, the image analysis of the first registration pattern 41A is performed to obtain the center position of the first registration pattern 41A. In contrast, in the third embodiment, after the first pattern matching area 42A and the second pattern matching area 42B are detected, the positions of the first registration pattern 41A and the second registration pattern 41B are calculated without performing the image analysis of the first registration pattern 41A and the second registration pattern 41B. Accordingly, an excellent advantage of short calculation time is achieved in the mounting of the electronic component 40.

A modification of the third embodiment will now be described with reference to FIG. 9. FIG. 9 is a diagram illustrating the pattern surface of the electronic component 40 to be targeted in a component mounting apparatus according to the modification of the third embodiment.

In the third embodiment (FIG. 8), the position of the registration pattern representative point 45 is obtained using the two pattern matching areas: the first pattern matching area 42A and the second pattern matching area 42B. In contrast, in the modification illustrated in FIG. 9, the position of the registration pattern representative point 45 is obtained using the only one first pattern matching area 42A. A geometrical center 42AC of the first pattern matching area 42A is adopted as the registration pattern representative point 45.

The position of the registration pattern representative point 45 may be obtained based on the only one first pattern matching area 42A, as in the modification of the third embodiment illustrated in FIG. 9.

### Fourth Embodiment

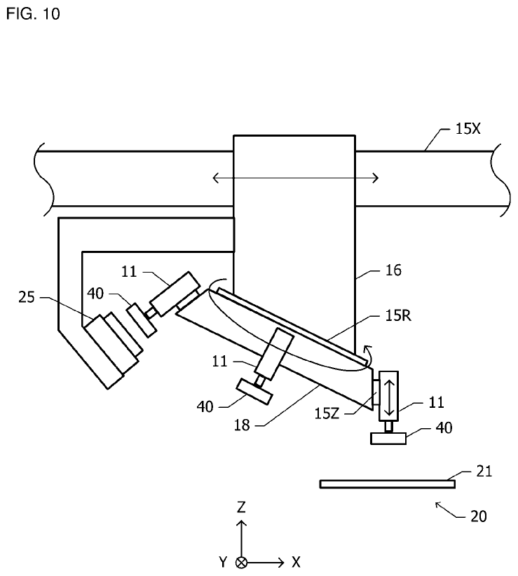

A component mounting apparatus according to a fourth embodiment will herein be described with reference to FIG. 10. A description of the configuration common to that of the component mounting apparatus according to the first embodiment described above with reference to FIG. 1 to FIG. 6B is omitted herein.

FIG. 10 is a schematic front view of part of the component mounting apparatus according to the fourth embodiment. In the first embodiment (FIG. 1), after the mounting nozzle 11 picks up the electronic component 40 at the component supply location 20, the X-direction movement mechanism 15X is operated to move the electronic component 40 into the angle of view of the camera 25. In contrast, in the fourth embodiment, the X-direction movement mechanism 15X is not involved in the operation to move the electronic component 40 picked up by the mounting nozzle 11 into the angle of view of the camera 25.

As illustrated in FIG. 10, a nozzle support member 16 is supported by the X-direction movement mechanism 15X so as to move in the X direction. A rotation member 18 is supported so as to be capable of rotation at the lower end portion of the nozzle support member 16 via a rotation mechanism 15R. A rotation central axis of the rotation member 18 is tilted with respect to the Z-axis direction. Multiple mounting nozzles 11 are mounted to the rotation member 18 via the corresponding Z-direction movement mechanisms 15Z.

The camera 25 is fixed to the nozzle support member 16. Upon rotation of the rotation member 18, each of the multiple mounting nozzles 11 performs a go-around movement to return from a position where the mounting nozzle 11 is opposed to the wafer 21 at the component supply location 20 to the position opposed to the wafer 21 via a position opposed to the camera 25. The mounting nozzle 11 is moved in the Z direction in response to an operation of the Z-direction movement mechanism 15Z in the state in which the mounting nozzle 11 is opposed to the wafer 21 to enable picking-up of the electronic component 40.

After the electronic component 40 is picked up, operating the rotation mechanism 15R enables the electronic component 40 that is picked up to be within the angle of view of the camera 25. At this time, it is not necessary to operate the X-direction movement mechanism 15X. After all the multiple mounting nozzles 11 pick up the electronic components 40, the X-direction movement mechanism 15X is operated to move the nozzle support member 16 to the component mounting location 27 (FIG. 1). At this stage, the images of the pattern surfaces of the electronic components 40 that have passed the angle of view of the camera 25 in response to the operation of the rotation mechanism 15R have been captured and the images of the pattern surfaces of the remaining electronic components 40 are not captured.

After the nozzle support member 16 is moved to the component mounting location 27, an operation to rotate the rotation member 18 by a predetermined angle in response to the operation of the rotation mechanism 15R and an operation to move up and down the mounting nozzle 11 in response to the operation of the Z-direction movement mechanism 15Z are repeated to mount the electronic component 40 on the substrate 29 (FIG. 1) at the component mounting location 27. The electronic components 40 the images of the pattern surfaces of which are not captured pass through the angle of view of the camera 25 in response to the operation of the rotation mechanism 15R during the mounting of the electronic component 40 and the images of the pattern surfaces are captured.

Excellent advantages of the fourth embodiment will now be described.

The mounting process of the electronic component 40 is capable of being simplified and the mounting position accuracy of the electronic components 40 is capable of being improved also in the fourth embodiment, as in the first embodiment. In addition, in the fourth embodiment, the images of the pattern surfaces of the electronic components 40 picked up by other mounting nozzles 11 are capable of being captured during a period in which one mounting nozzle 11 is picking up the electronic component 40 or during a period in which the electronic component 40 picked by one mounting nozzle 11 is being mounted on the substrate 29. Accordingly, it is possible to improve the throughput of the process to mount the electronic components.

The respective embodiments described above are only examples and partial replacement or combination of the components described in different embodiments is available. The same effects and advantages of the same components in multiple embodiments are not successively described in the respective embodiments. In addition, the present disclosure is not limited to the above embodiments. For example, availability of various modifications, improvements, combinations, and so on is obvious to the person skilled in the art.

The following disclosure is disclosed based on the above embodiments described in this specification.

<1> A component mounting apparatus comprising a mounting nozzle configured to be capable of holding an electronic component having a plurality of patterns provided on its pattern surface based on pattern design information; a camera configured to be capable of capturing an image of the pattern surface of the electronic component; a movement mechanism configured to be capable of moving the mounting nozzle between a location where capturing of the image by the camera is performed and a component mounting location; and a control unit configured to be capable of controlling the mounting nozzle and the movement mechanism. The control unit has a function to store positional relationship information indicating positional relationship based on the pattern design information between a position of a registration pattern representative point identified by at least one registration pattern selected from the plurality of patterns provided on the pattern surface and a position of a positioning reference point on which positioning of the electronic component at the component mounting location for mounting is based, and a function to acquire an image of the pattern surface of the electronic component, which is captured by the camera. The control unit also has a function to analyze the image to obtain the position of the registration pattern representative point, and a function to position the positioning reference point obtained from the position of the registration pattern representative point resulting from the analysis of the image and the positional relationship information at a target position at the component mounting location to mount the electronic component.

<2> The component mounting apparatus described in <1>, wherein a plurality of patterns is registered as the registration pattern, and wherein the registration pattern representative point is a geometrical center of the plurality of registration patterns.

<3> The component mounting apparatus described in <1> or <2>, wherein a template of a pattern matching area including the registration pattern is stored, and wherein the control unit performs a pattern matching process using the template to the image captured by the camera to obtain the position of the registration pattern representative point based on a result of the pattern matching.

<4> The component mounting apparatus described in any of <1> to <3>, further comprising a display unit configured to display the image captured by the camera; and an input unit configured to select at least one pattern from the plurality of patterns in the image displayed in the display unit as the registration pattern in accordance with an operation by a user. The control unit further has a function to display the image captured by the camera in the display unit, and a function to store the pattern selected in accordance with the operation with the input unit as the registration pattern.

<5> The component mounting apparatus described in <4>, wherein the control unit stores a frequently appearing pattern, among the plurality of patterns on the pattern surface, and wherein the control unit displays the frequently appearing pattern in the display unit so as to be capable of being discriminated from the other patterns in the function to display the image captured by the camera in the display unit.

<6> A component mounting method comprising acquiring in advance positional relationship information indicating positional relationship based on pattern design information between a position of a registration pattern representative point identified by at least one registration pattern selected from a plurality of patterns provided on a pattern surface of an electronic component based on the pattern design information and a position of a positioning reference point on which positioning of the electronic component at a component mounting location for mounting is based; and holding the electronic component with a mounting nozzle. The component mounting method further comprises acquiring an image of the pattern surface of the electronic component held with the mounting nozzle; analyzing the image to obtain the position of the registration pattern representative point; and positioning the positioning reference point obtained from the position of the registration pattern representative point resulting from the analysis of the image and the positional relationship information at a target position at the component mounting location to mount the electronic component.

<7> The component mounting method described in <6>, wherein a plurality of patterns is registered as the registration pattern, and wherein the registration pattern representative point is a geometrical center of the plurality of registration patterns.

<8> The component mounting method described in <6> or <7>, wherein, in obtaining of the position of the registration pattern representative point, a pattern matching process is performed to the acquired image using a template that is prepared in advance to obtain the position of the registration pattern representative point based on a result of the pattern matching.

<9> The component mounting method described in any of <6> to <8>, wherein a user selects at least one pattern from the plurality of patterns on the pattern surface as the registration pattern, and wherein the positional relationship information between the position of the registration pattern representative point resulting from the analysis of the image and the position of the positioning reference point is obtained using the pattern design information.

<10> A positional relationship information acquiring method comprising acquiring an image of a pattern surface having a plurality of patterns formed thereon of an electronic component; displaying the image to cause a user to select a registration pattern from the plurality of patterns and to cause the user to specify a pattern matching area including some patterns in the plurality of patterns; and storing information for identifying the registration pattern selected by the user and information for identifying the pattern matching area specified by the user. The positional relationship information acquiring method also comprises calculating a position of a registration pattern representative point based on pattern design information that defines shapes and positions of the plurality of patterns on the pattern surface and the information for identifying the registration pattern; calculating positional relationship between a positioning reference point on which positioning to a target position where the electronic component is to be mounted is based and the position of the registration pattern representative point based on the pattern design information; and acquiring and storing positional relationship information between the positioning reference point and the registration pattern representative point.

What is claimed is:

1. A component mounting apparatus comprising:
a mounting nozzle configured to hold an electronic component having a plurality of patterns on its pattern surface based on pattern design information;
a camera configured to capture an image of the pattern surface of the electronic component;
a movement mechanism configured to move the mounting nozzle between a location where capturing of the image by the camera is performed and a component mounting location; and
a controller configured to control the mounting nozzle and the movement mechanism,
wherein the controller is further configured to
store positional relationship information indicating positional relationship based on the pattern design information between a position of a registration pattern representative point identified by at least one registration pattern selected from the plurality of patterns on the pattern surface and a position of a positioning reference point on which positioning of the electronic component at the component mounting location for mounting is based,
acquire an image of the pattern surface of the electronic component, which is captured by the camera,
analyze the image to obtain the position of the registration pattern representative point, and
position the positioning reference point obtained from the position of the registration pattern representative point resulting from the analysis of the image and the positional relationship information at a target position at the component mounting location to mount the electronic component.

2. The component mounting apparatus according to claim 1, wherein
a plurality of patterns is registered as the registration pattern, and
the at least one registration pattern includes a plurality of registration patterns, and the registration pattern representative point is a geometrical center of the plurality of registration patterns.

3. The component mounting apparatus according to claim 1, wherein
a template of a pattern matching area including the registration pattern is stored, and
the controller is configured to perform a pattern matching process using the template to the image captured by the camera to obtain the position of the registration pattern representative point based on a result of the pattern matching.

4. The component mounting apparatus according to claim 1, further comprising:
a display configured to display the image captured by the camera; and
an input configured to select at least one pattern from the plurality of patterns in the image displayed in the display as the registration pattern in accordance with an operation by a user,
wherein the controller is further configured to
display the image captured by the camera in the display, and
store the pattern selected in accordance with the operation with the input as the registration pattern.

5. The component mounting apparatus according to claim 4, wherein
the controller is configured to store a frequently appearing pattern, among the plurality of patterns on the pattern surface, and
the controller is configured to display the frequently appearing pattern in the display such that the frequently appearing pattern is discriminated from the other patterns to display the image captured by the camera in the display.

6. The component mounting apparatus according to claim 2, wherein
a template of a pattern matching area including the registration pattern is stored, and
the controller is configured to perform a pattern matching process using the template to the image captured by the camera to obtain the position of the registration pattern representative point based on a result of the pattern matching.

7. The component mounting apparatus according to claim 2, further comprising:
a display configured to display the image captured by the camera; and
an input configured to select at least one pattern from the plurality of patterns in the image displayed in the display as the registration pattern in accordance with an operation by a user,
wherein the controller is further configured to
display the image captured by the camera in the display, and
store the pattern selected in accordance with the operation with the input as the registration pattern.

8. The component mounting apparatus according to claim 7, wherein
the controller is configured to store a frequently appearing pattern, among the plurality of patterns on the pattern surface, and
the controller is configured to display the frequently appearing pattern in the display such that the frequently appearing pattern is discriminated from the other patterns to display the image captured by the camera in the display.

9. A component mounting method comprising:
acquiring in advance positional relationship information indicating positional relationship based on pattern design information between a position of a registration pattern representative point identified by at least one registration pattern selected from a plurality of patterns on a pattern surface of an electronic component based on the pattern design information and a position of a positioning reference point on which positioning of the electronic component at a component mounting location for mounting is based;
holding the electronic component with a mounting nozzle;
acquiring an image of the pattern surface of the electronic component held with the mounting nozzle;
analyzing the image to obtain the position of the registration pattern representative point; and
positioning the positioning reference point obtained from the position of the registration pattern representative point resulting from the analysis of the image and the positional relationship information at a target position at the component mounting location to mount the electronic component.

10. The component mounting method according to claim 9, wherein
a plurality of patterns is registered as the registration pattern, and
the at least one registration pattern includes a plurality of registration patterns, and the registration pattern representative point is a geometrical center of the plurality of registration patterns.

11. The component mounting method according to claim 9, wherein
in obtaining of the position of the registration pattern representative point, a pattern matching process is performed to the acquired image using a template that is prepared in advance to obtain the position of the registration pattern representative point based on a result of the pattern matching.

12. The component mounting method according to claim 10, wherein
in obtaining of the position of the registration pattern representative point, a pattern matching process is performed to the acquired image using a template that is prepared in advance to obtain the position of the registration pattern representative point based on a result of the pattern matching.

13. The component mounting method according to claim 9, wherein
a user selects at least one pattern from the plurality of patterns on the pattern surface as the registration pattern, and
wherein the positional relationship information between the position of the registration pattern representative point resulting from the analysis of the image and the position of the positioning reference point is obtained using the pattern design information.

14. The component mounting method according to claim 10, wherein
a user selects at least one pattern from the plurality of patterns on the pattern surface as the registration pattern, and
wherein the positional relationship information between the position of the registration pattern representative point resulting from the analysis of the image and the position of the positioning reference point is obtained using the pattern design information.

15. A positional relationship information acquiring method comprising:
acquiring an image of a pattern surface having a plurality of patterns thereon of an electronic component;
displaying the image to cause a user to select a registration pattern from the plurality of patterns and to cause the user to specify a pattern matching area including some patterns in the plurality of patterns;
storing information for identifying the registration pattern selected by the user and information for identifying the pattern matching area specified by the user;
calculating a position of a registration pattern representative point based on pattern design information that defines shapes and positions of the plurality of patterns on the pattern surface and the information for identifying the registration pattern;
calculating positional relationship between a positioning reference point on which positioning to a target position where the electronic component is to be mounted is based and the position of the registration pattern representative point based on the pattern design information; and
acquiring and storing positional relationship information between the positioning reference point and the registration pattern representative point.
